(19) United States
(12) Patent Application Publication
(10) Pub. No.: US 2006/0275933 A1
(43) Pub. Date: Dec. 7, 2006

(54) Thermally conductive ceramic tipped contact thermocouple

(75) Inventors: Dale R. Du Bois, Los Gatos, CA (US); Juan Carlos Rocha-Alvarez, Sunnyvale, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/143,270

(22) Filed: Jun. 2, 2005

(51) Int. Cl. H01L 21/66; H01L 23/58; G01K 7/00

(52) U.S. Cl. 438/14; 374/179; 257/48

(57) ABSTRACT

An apparatus for processing a substrate. The apparatus comprising a tubular member with a first end and a second end. The first end comprising an opening; and a temperature sensor disposed in the opening. The temperature sensor comprising a resilient member. The resilient member comprising a surface made of a ceramic material wherein the surface made of a ceramic material extends through the opening to provide a substrate contact surface.

### BACKGROUND OF THE INVENTION

1. Field of the Invention

Embodiments of the present invention generally relate to temperature measurement technology. More particularly, embodiments of the present invention relate to a device for temperature measurement in a semiconductor processing environment.

2. Description of the Related Art

Semiconductor device geometries have dramatically decreased in size since such devices were first introduced several decades ago. Since then, integrated circuits have generally followed the two year/half-size rule (often called Moore's Law), which means that the number of devices that will fit on a chip doubles every two years. Today's fabrication plants are routinely producing devices having 0.13 μm and even 0.1 μm feature sizes, and tomorrow's plants will soon be producing devices having even smaller geometries.

In order to further reduce the size of devices on integrated circuits; it has become necessary to use conductive materials having low resistivity and to use insulators having low dielectric constants (k) to reduce the capacitive coupling between adjacent metal lines. Recent developments in low dielectric constant insulating films have focused on incorporating silicon (Si), carbon (C), and oxygen (O) atoms into the films. One challenge in this area has been to develop a Si, C, and O containing film that has a low k value and also exhibits desirable thermal and mechanical properties. Often Si, C, and O containing films that have a desirable dielectric constant exhibit poor mechanical strength and are easily damaged by etch chemistry and plasma exposure during subsequent processing, causing failure of the integrated circuit.

Thermal and plasma annealing processes have been developed in attempts to improve the properties of low dielectric constant films. Thermal and plasma annealing processes have typically been performed at temperatures of less than about 400° C. in order to prevent damage to other components of the substrate or device on which the low dielectric constant film is deposited. As a result, the ability to monitor the temperature at the substrate surface is an important component of the annealing process. Further, industry production requirements dictate several criteria that must be met when selecting a temperature sensing device or thermocouple.

First, the junction of the thermocouple device must make direct, reliable thermal contact with the surface to be monitored. Otherwise, there is a thermal impedance between the thermocouple junction and the surface resulting in temperature readings more closely related to the material surrounding the thermocouple than to the actual surface temperature.

Second, the mass of material surrounding the thermocouple junction and holding it to the surface should be minimal. The effect of this material is to add thermal mass to the junction and insulation surface beneath the material, both of which cause the thermocouple to lag the true surface temperature.

Finally, the thermocouple surface should not introduce contaminants onto the surface being measured. While a number of thermocouple devices are currently known, they all use a copper tip to maximize temperature response. Unfortunately, using the copper tip against a surface, such as a silicon wafer surface, causes contamination problems. Other metals such as aluminum, nickel and molybdenum face the same problems.

For the foregoing reasons, there is a need for a temperature measurement device with a good response time, reliable thermal contact, and comprising a material that won't contaminate the object whose temperature is measured.

### SUMMARY OF THE INVENTION

Accordingly, the present invention provides a thermocouple assembly that solves the aforementioned problems.

Embodiments of the present invention provide an apparatus for processing a substrate comprising a tublular member with a first end and a second end. The first end has an opening and a temperature sensor disposed in the opening. The temperature sensor has a resilient member attached to a surface made of a ceramic material. The surface made of a ceramic material extends through the opening to provide a substrate contact surface.

In another embodiment, the present invention comprises an apparatus for processing a substrate. The apparatus has a thermocouple tip having at least a first portion of a conductor. The thermocouple tip comprises a tubular member with a first end and a second end, the first end comprising an opening with a temperature sensor disposed in the opening. The temperature sensor comprises a resilient member attached to a surface made of a ceramic material. The surface made of ceramic material extends through the opening. The apparatus also has a connector having at least a second portion of the conductor, and a length of cable comprising an insulator and at least a third portion of the conductor coupling at least the first portion of the conductor with at least the second portion of the conductor.

Further embodiments include an apparatus for processing a substrate comprising a vacuum chamber, a cathode, an anode and a thermocouple. The thermocouple comprising a thermocouple tip having at least a first portion of a conductor wherein the thermocouple tip comprises a tubular member with a first end and second end, the first end comprising an opening with a temperature sensor disposed in the opening. The temperature sensor comprises a resilient member and a surface made of a ceramic material wherein the surface made of ceramic material extends throught the opening. The thermocouple assembly also has a connector having at least a second portion of a conductor. The thermocouple assembly further comprises a length of cable comprising an insulator and at least a third portion of the conductor coupling at least the first portion of the conductor with the second portion of the conductor, the insulator encasing at least a portion of the conductor and a bushing disposed around the length of cable.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional diagram of an exemplary processing chamber.

FIG. 2 is a perspective view of one embodiment of the thermocouple assembly.

FIG. 3 is a perspective view of one embodiment of the thermocouple tip shown in FIG. 2.

FIG. 4 is a cross sectional view of the exemplary thermocouple assembly of FIG. 2 taken along line 4-4 on FIG. 2.

FIG. 5A is a schematic view of the thermocouple tip upon initially contacting a substrate.

FIG. 5B is a schematic view of the thermocouple tip after contacting the substrate.

### DETAILED DESCRIPTION

Embodiments of the present invention provide a thermocouple assembly comprising a ceramic tip. These embodiments may be used in other processing chambers including but not limited to CVD, PVD, PECVD or any other processing or manufacturing chambers requiring temperature monitoring.

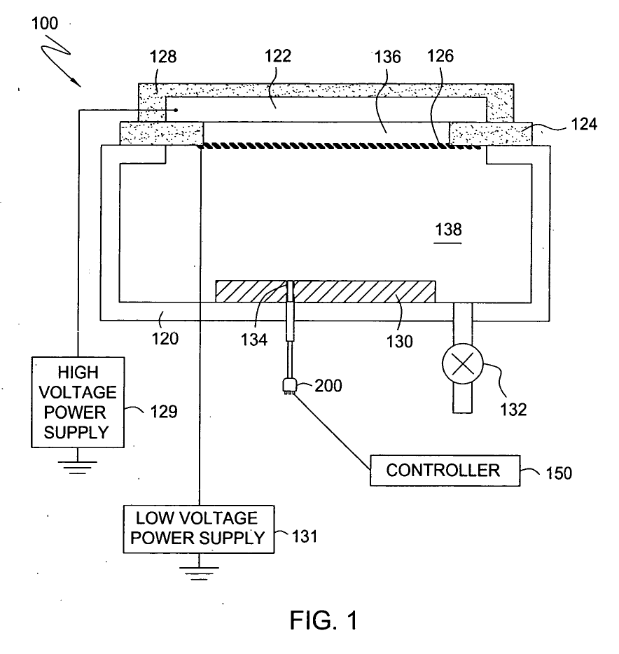

FIG. 1 is a cross-sectional diagram of an exemplary processing chamber 100, the e-beam chamber, in accordance with an embodiment of the invention. The e-beam chamber 100 includes a vacuum chamber 120, a large-area cathode 122, a target plane or substrate support 130 located in a field-free region 138, and a grid anode 126 positioned between the target plane 130 and the large-area cathode 122. The target plane 130 contains at least one hole 134 that extends through the vacuum chamber 120, for embedding a temperature measuring element such as a thermocouple assembly 200. The thermocouple assembly 200 is connected to a controller 150. The e-beam chamber 100 further includes a high voltage insulator 124 and an accelerating field region 136 which isolates the grid anode 126 from the large-area cathode 122, a cathode cover insulator 128 located outside the vacuum chamber 120, a variable leak valve 132 for controlling the pressure inside the vacuum chamber 120, a variable high voltage power supply 129 connected to the large-area cathode 122, and a variable low voltage power supply 131 connected to the grid anode 126.

Other details of the e-beam chamber 100 are described in U.S. Pat. No. 5,003,178, entitled “Large-Area Uniform Electron Source,” issued Mar. 26, 1991, and herein incorporated by reference to the extent not inconsistent with the invention.

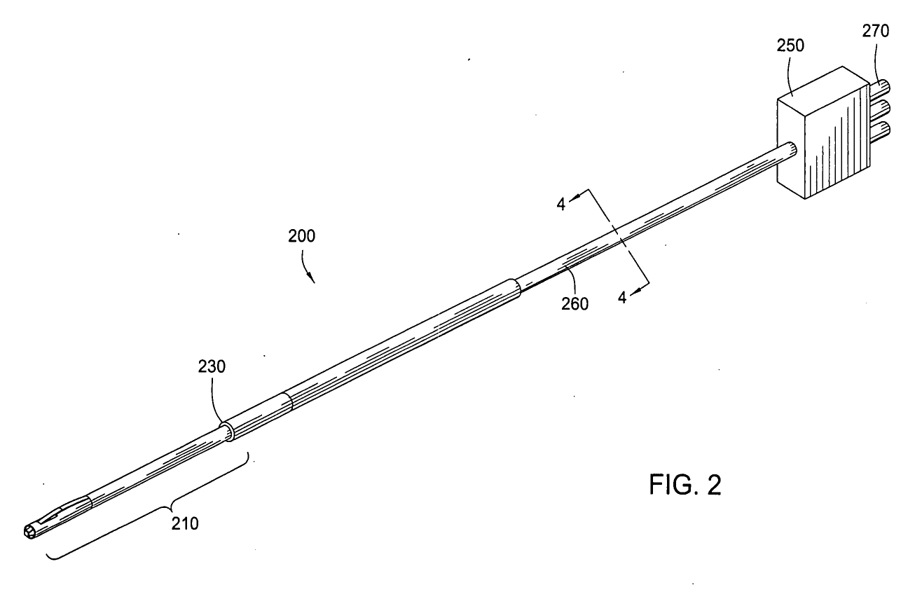

FIG. 2 is a perspective view of one embodiment of the thermocouple assembly 200. The thermocouple assembly 200 of this embodiment comprises a thermocouple tip 210 coupled to a bushing 230. The thermocouple tip 210 and tapered bushing 230 are attached via a length of cable or cable segment 420 (see FIG. 4) to a backshell 250 via a protective tube 260 surrounding the cable segment 420. The backshell 250 houses a plurality of bent contacts (not shown), each coupled both to a conductor 410 of the thermocouple assembly 200 (e.g. by welding) and to a corresponding pin (not shown) of a connector 270.

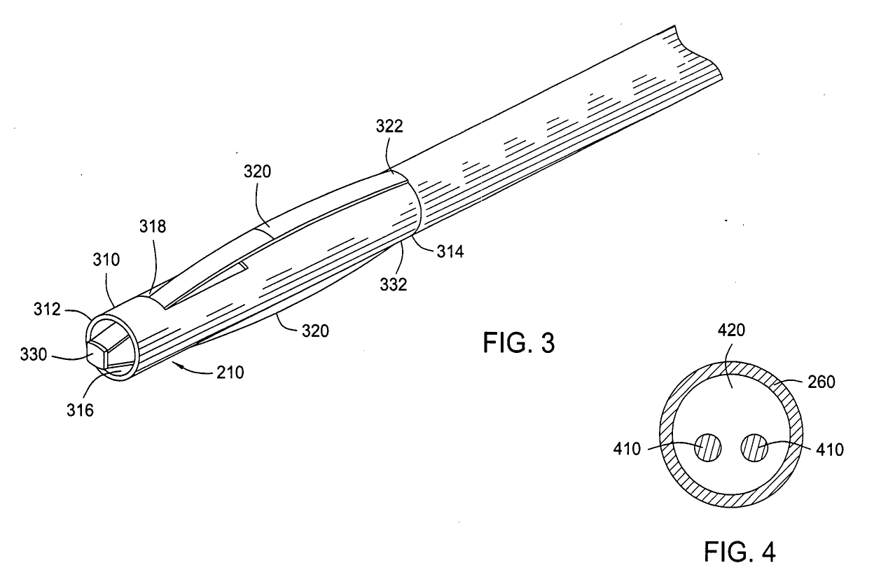

FIG. 3 is a perspective view of one embodiment of the thermocouple tip 210 shown in FIG. 2. The thermocouple tip 210 comprises a tubular member 310 with a first end 312 and a second end 314. The tubular member 310 has an opening 316 and a pair of slots 318 formed on the surface of the tubular member 310 through each of which passes a resilient member 320 with two ends 322 and 332. The ends 322 and 332 of the resilient member 320 are attached to the outer surface of the tubular member 310 at the second end 314 by brazing or other attachment methods known in the art. A contact surface 330 is attached to the resilient member 320 by brazing or other common attachment methods known in the art. The resilient member 320 is biased so that the contact surface 330 protrudes out of the opening 316 of the first end 312 of the tubular member 310. A conductor 410 comprising two wires, shown in FIG. 4, is attached to the inner side of the contact surface 330 by brazing or other common attachment methods known in the art, thus forming a thermocouple junction or temperature sensor.

The contact surface 330 can be any shape but preferably has a low mass with a smooth surface. The contact surface 330 is preferably made of a ceramic material selected from the group consisting of silicon carbide, silicon nitride, aluminum nitride, synthetic diamond and derivatives thereof. Other materials possessing fast response time and excellent thermal conductivity that do not react with process chemistries are also acceptable. The choice between these materials is process dependent.

The resilient member 320 is preferably a spring loaded device like a leaf spring, compression spring, flat spring, or conical spring but can also be any resilient or bendable wire providing the desired characteristics. The resilient member 320 is of such length and shape so that in both the resilient member's 320 compressed and uncompressed state the resilient member 320 extends past the opening 316 of the first end 312 of the tubular member 310. Full contact between the thermocouple junction and the substrate surface is assured by the over travel allowance of the thermocouple tip 210. Further, full contact with the substrate surface is assured by the gimbal action of the thermocouple tip 210. The resilient member 320 comprises any suitable spring type material such as aluminum, stainless steel (e.g. INCONEL®) and other high strength, corrosion resistant metal alloys that do not react with process chemistries.

FIG. 4 is a cross sectional view of the exemplary thermocouple assembly 200 of FIG. 2 taken along line 4-4. FIG. 4 shows the cable segment 420 enclosed within the protective tube 260. The cable segment 420 comprises insulated cable which has sufficient flexibility to resist breakage when the entire thermocouple assembly 200 is fixed at either end but stiff enough to allow the cable segment 420 to be inserted into the protective tube 260. The cable segment 420 comprises at least one conductor 410 insulated with a highly compressed refractory mineral insulation enclosed in a liquid-tight and gas-tight continuous protective tube 260. The protective tube 260 comprises any suitable material such as aluminum, stainless steel (e.g. INCONEL®) and other high strength, corrosion resistant metal alloys that do not react with process chemistries.

The conductor 410 is attached by brazing or other attachment methods known in the art to the opposite surface of the contact surface 330 to form the thermocouple junction attached to the resilient member 320. If the conductor 410 is soldered to the contact surface 330, care must be taken to use a minimal amount of solder because a large mass of solder will decrease the rate of response by conducting heat away from the junction and will also interfere with the proper flexure of the resilient member 320.

The thermocouple is inserted into the hole 134 of the e-beam chamber 100 of FIG. 1 such that the tapered bushing 230 of the thermocouple assembly 200 mates against a tapered stop (not shown) formed within the hole 134 of the e-beam chamber 100, and the contact surface 330 extends beyond the hole 134 and is disposed in the vacuum chamber. The tapered bushing 230 and the stop, when mated together, form a stop mechanism that secures the thermocouple assembly 200 to the e-beam chamber 100, stops the thermocouple assembly 200 when proper contact between the substrate surface (not shown) and the thermocouple contact surface 330 are achieved and also forms a seal. The stop mechanism also makes the thermocouple assembly 200 easily removable. Tapered surfaces are used in the stop mechanism to allow easy disengagement of the thermocouple assembly 200. Those skilled in the art should recognize that the tapered bushing 230 and stop do not necessarily have to be tapered and may be of any shape and size adapted to mate with one another.

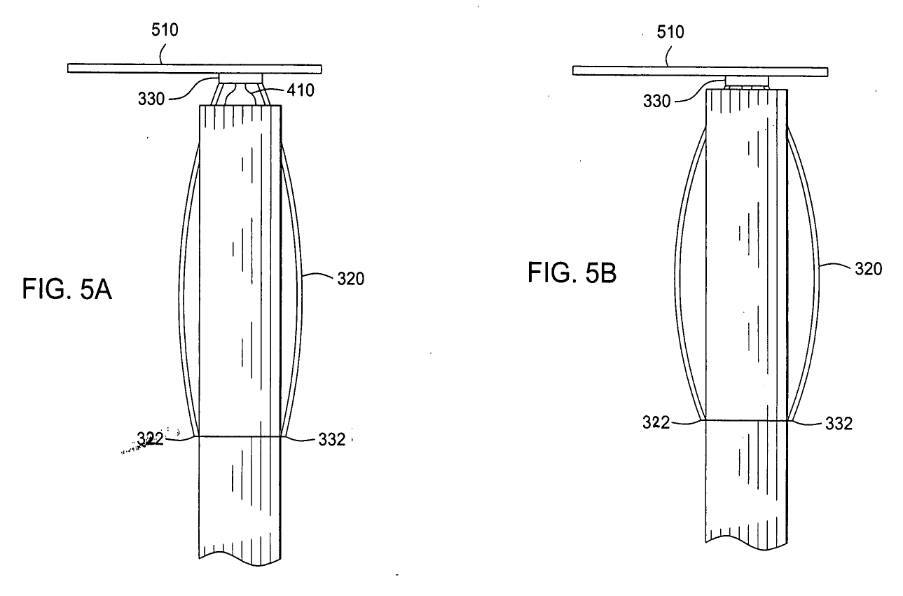

In operation, the substrate with the low dielectric constant film thereon to be exposed with the electron beam is placed on the target plane 130. FIG. 5A is a schematic view of the contact surface 330 and resilient member 320 of the thermocouple tip 210 upon initially contacting a substrate surface 510. The resilient member 320 is in an unbiased position. As shown in FIG. 5B, when the substrate surface 510 makes contact with the contact surface 330 of the thermocouple tip 210, the downward force provided by the weight of the substrate surface 510 biases the resilient member 320. The biasing of the resilient member 320 allows the contact surface 330 to maintain contact with the substrate surface 510 while also allowing the substrate to contact the target plane 130.

During processing, a voltage is developed between the two wires of the conductor attached at the thermocouple junction and the unattached end of the wires or reference junction which is maintained at a known temperature. The difference in temperature between the thermocouple junction and the reference junction generates an electromotive force that is proportional to the temperature difference. This measured voltage is transmitted through the conductor 410 to the controller 150 and used to determine the temperature of the substrate.

Aspects of the processing chamber 100 are operated by a control system. The control system may include any number of controllers, such as controller 150, processors and input/output devices. In one embodiment, the control system is a component of a closed loop feedback system which monitors various parameters within the process chamber 100 while processing a substrate, and then issues one or more control signals to make necessary adjustments according to various setpoints. In general, the parameters being monitored include temperature, pressure, and gas flow rates.

Thus, embodiments of the invention provide a temperature measurement device with a good response time, reliable thermal contact, and comprising a material that won't contaminate the object whose temperature is measured.

While the foregoing is directed to embodiments of the present invention, other and further embodiments of the invention may be devised without departing from the basic scope thereof, and the scope thereof is determined by the claims that follow.

What is claimed is:

1. An apparatus for processing a substrate comprising:
a tubular member with a first end and a second end, the first end comprising:
an opening; and
a temperature sensor disposed in the opening, wherein the temperature sensor comprises a resilient member attached to a surface made of a ceramic material wherein the surface made of the ceramic material extends through the opening to provide a substrate contact surface.

2. An apparatus as claimed in claim 1, wherein the ceramic material is selected from the group consisting of silicon carbide, silicon nitride, aluminum nitride, synthetic diamond, and derivatives thereof.

3. An apparatus as claimed in claim 2, wherein the surface comprises a smooth surface.

4. An apparatus as claimed in claim 1, wherein the resilient member comprises a spring loaded member.

5. An apparatus as claimed in claim 4, wherein the spring loaded member further comprises a spring selected from the group consisting of a leaf spring, a compression spring, a flat spring, and a conical spring.

6. An apparatus as claimed in claim 1 wherein the temperature sensor further comprises at least a first portion of a conductor.

7. An apparatus as claimed in claim 6 further comprising a connector having at least a second portion of the conductor.

8. An apparatus as claimed in claim 7 further comprising a length of cable, the length of cable comprising at least a third portion of the conductor, the third portion of the conductor coupling at least the first portion of the conductor with the second portion of the conductor.

9. An apparatus for processing a substrate comprising:
a thermocouple tip having at least a first portion of a conductor wherein the thermocouple tip comprises:
a tubular member with a first end and a second end, the first end comprising an opening with a temperature sensor disposed in the opening, wherein the temperature sensor comprises:
a resilient member attached to a surface made of a ceramic material wherein the surface made of the ceramic material extends through the opening;
a connector having at least a second portion of the conductor; and
a length of cable comprising an insulator and at least a third portion of the conductor coupling at least a first portion of the conductor with at least a second portion of the conductor.

10. An apparatus as claimed in claim 9, wherein the ceramic material is selected from the group consisting of silicon carbide, silicon nitride, aluminum nitride, synthetic diamond, and derivatives thereof.

11. An apparatus as claimed in claim 9, wherein the resilient member comprises a spring loaded member selected from the group consisting of a leaf spring, a compression spring, a flat spring, and a conical spring.

12. An apparatus as claimed in claim 9, further comprising a backshell adjacent to the connector, wherein the connector is coupled to the backshell and the second portion of the conductor is coupled to the third portion of the conductor within the backshell.

13. An apparatus as claimed in claim 9, further comprising a bushing disposed around the length of cable.

14. An apparatus as claimed in claim 13 wherein the bushing is adapted to mate with a corresponding stop in a device for housing the apparatus.

15. An apparatus as claimed in claim 9, further comprising a protective tube disposed around at least a portion of the length of cable.

16. An apparatus for processing a substrate comprising:
a vacuum chamber;
a cathode;
an anode; and
a thermocouple assembly comprising:
a thermocouple tip having at least a first portion of the conductor wherein the thermocouple tip comprises:
a tubular member with a first end and a second end, the first end comprising an opening with a temperature sensor disposed in the opening, wherein the temperature sensor comprises:
a resilient member and a surface made of a ceramic material wherein the surface made of ceramic material extends through the opening;
a connector having at least a second portion of the conductor;
a length of cable comprising an insulator and at least a third portion of the conductor coupling at least the first portion of the conductor with at least the second portion of the conductor, the insulator encasing at least a portion of the conductor; and
a bushing disposed around the length of cable.

17. An apparatus as claimed in claim 16, wherein the ceramic material is selected from the group consisting of silicon carbide, silicon nitride, aluminum nitride, synthetic diamond and derivatives thereof.

18. An apparatus as claimed in claim 17, wherein the surface comprises a smooth surface.

19. An apparatus as claimed in claim 18, wherein the resilient member comprises a spring loaded member.

20. An apparatus as claimed in claim 19, wherein the spring loaded member further comprises a spring selected from the group consisting of a leaf spring, a compression spring, a flat spring, and a conical spring.
